(19) United States
(12) Patent Application Publication
(10) Pub. No.: US 2026/0279395 A1
(43) Pub. Date: Sep. 17, 2026

(54) MULTI-BEAM WRITING APPARATUS AND MULTI-BEAM WRITING METHOD

(71) Applicant: NuFlare Technology, Inc., Yokohama-shi (JP)

(72) Inventors: Haruyuki NOMURA, Yokohama-shi (JP); Jumpei YASUDA, Kamakura-shi (JP); Hiroshi MATSUMOTO, Yokohama-shi (JP)

(73) Assignee: NuFlare Technology, Inc., Yokohama-shi (JP)

(21) Appl. No.: 19/445,914

(22) Filed: Jan. 12, 2026

(30) Foreign Application Priority Data
Mar. 12, 2025 (JP) 2025-039783

(51) Int. Cl. G11B 7/0045; G11B 7/09

(52) U.S. Cl. CPC G11B 7/00455; G11B 7/0903

(57) ABSTRACT

A multi-beam writing apparatus includes a stripe region generation circuit configured to generate a plurality of first stripe regions by dividing a writing region of the substrate such that a longer direction of each of the plurality of first stripe regions is in a first direction, and a plurality of second stripe regions by dividing the writing region of the substrate such that a longer direction of each of the plurality of second stripe regions is in a second direction having a predetermined relative angle to the first direction, and a writing mechanism configured to perform writing to a group of the first stripe region and the second stripe region while moving the irradiation region of the multiple beams between the first stripe region and the second stripe region in a same group during one movement of a stage to move the writing in a writing direction.

### CROSS-REFERENCE TO RELATED APPLICATION

This application is based upon and claims the benefit of priority from prior Japanese Patent Application No. 2025-039783 filed on Mar. 12, 2025 in Japan, the entire contents of which are incorporated herein by reference.

### BACKGROUND OF THE INVENTION

### Field of the Invention

Embodiments of the present invention relate to a multi-beam writing apparatus and a multi-beam writing method, and, for example, to a writing method performed by a multi-beam writing apparatus.

### Description of Related Art

The lithography technique which advances miniaturization of semiconductor devices is extremely important as a unique process in which patterns are formed in semiconductor manufacturing. In recent years, with high integration of LSI, the line width (critical dimension) necessary for semiconductor device circuits is decreasing year by year. The electron beam writing technique, which intrinsically has excellent resolution, is used for writing or “drawing” patterns on a wafer and the like with electron beams.

For example, as a known example of employing the electron beam writing technique, there is a writing apparatus using multiple beams. Since writing with multiple beams can apply a lot of beams at a time, the writing throughput can be greatly increased compared to writing with a single electron beam. For example, a writing apparatus employing the multiple beam system forms multiple beams by letting an electron beam emitted from an electron gun pass through a mask having a plurality of holes, performs blanking control for each beam, reduces each unblocked beam to generate a reduced mask image by an optical system, and deflects, by a deflector, a reduced beam to be applied to a desired position on a target object or “sample”.

As for the multiple beam writing, if there is a defective beam whose dose is difficult to control in multiple beams, a certain portion happens to be written periodically by the defective beam. When the direction of writing with the multiple beams is coincident with the longer direction of the side forming a pattern edge, a problem has occurred that cyclic errors and/or errors of a pattern written by the defective beam is generated. To cope with this problem, there is disclosed a method in which writing is performed in the state where the direction of the exposure stripe is inclined with respect to the direction of the main pattern (refer to Japanese Patent No. 6948765). However, since the writing apparatus cannot easily know/obtain the direction of a pattern edge in a pattern layout, an enormous amount of calculation is needed for obtaining the directions of all the pattern edges. Furthermore, due to so-called grid matching correction and the like, the direction of the pattern edge is not necessarily constant. Therefore, it is insufficient to perform writing while obliquely moving the stage.

### BRIEF SUMMARY OF THE INVENTION

According to one aspect of the present invention, a multi-beam writing apparatus includes
a stage configured to be movable and to mount thereon a substrate which is to be written with multiple beams,
a stripe region generation circuit configured to generate a plurality of first stripe regions by dividing a writing region of the substrate such that a longer direction of each of the plurality of first stripe regions is in a first direction, and a plurality of second stripe regions by dividing the writing region of the substrate such that a longer direction of each of the plurality of second stripe regions is in a second direction having a predetermined relative angle to the first direction, and
a writing mechanism configured to repeat tracking control so that an irradiation region of the multiple beams follows a movement of the stage, and to perform writing, during each the tracking control, regarding, as a group, a first stripe region of the plurality of first stripe regions and a second stripe region of the plurality of second stripe regions where some regions of the first stripe region and the second stripe region are overlapped with each other, to the group of the first stripe region and the second stripe region while moving the irradiation region of the multiple beams between the first stripe region and the second stripe region in a same group during one movement of the stage to move the writing in a writing direction.

According to another aspect of the present invention, a multi-beam writing method includes
placing a substrate to be written with multiple beams on a stage being movable,
generating a plurality of first stripe regions by dividing a writing region of the substrate such that a longer direction of each of the plurality of first stripe regions is in a first direction, and a plurality of second stripe regions by dividing the writing region of the substrate such that a longer direction of each of the plurality of second stripe regions is in a second direction having a predetermined relative angle to the first direction, and
repeating tracking control so that an irradiation region of the multiple beams follows a movement of the stage, and performing writing, during each the tracking control, regarding, as a group, a first stripe region of the plurality of first stripe regions and a second stripe region of the plurality of second stripe regions where some regions of the first stripe region and the second stripe region are overlapped with each other, to the group of the first stripe region and the second stripe region while moving the irradiation region of the multiple beams between the first stripe region and the second stripe region in a same group during one movement of the stage to move the writing in a writing direction.

### BRIEF DESCRIPTION OF THE DRAWINGS

FIG. 1 is a schematic diagram showing a configuration of a writing apparatus according to a first embodiment;

FIG. 2 is a conceptual diagram showing a configuration of a shaping aperture array substrate according to the first embodiment;

FIG. 3 is a sectional view showing a configuration of a blanking aperture array mechanism according to the first embodiment;

FIG. 4 is a conceptual diagram for explaining an example of a writing region and a stripe region according to the first embodiment;

FIG. 5 is an illustration of an example of an irradiation region of multiple beams and a writing target pixel according to the first embodiment;

FIG. 6 is an illustration of an example of beam arrays and written patterns according to a comparative example 1 of the first embodiment;

FIG. 7 is an illustration of an example of beam arrays and written patterns according to a comparative example 2 of the first embodiment;

FIG. 8 is an illustration of examples of a pattern layout before and after grid matching correction according to a comparative example 3 of the first embodiment;

FIG. 9 is a flowchart showing an example of main steps of a writing method according to the first embodiment;

FIG. 10 is an illustration showing an example of stripe regions whose respective angles in their longer directions are different from each other according to the first embodiment;

FIG. 11 is an illustration showing an example of the maximum relative angle between stripe regions whose respective angles in their longer directions are different from each other according to the first embodiment;

FIG. 12 is an illustration showing another example of a plurality of stripe regions whose respective angles in their longer directions are different from each other according to the first embodiment;

FIG. 13 is an illustration showing another example of a plurality of stripe regions whose respective angles in their longer directions are different from each other according to the first embodiment;

FIG. 14 is an illustration for explaining an example of a multiple beam writing operation according to the first embodiment;

FIG. 15 is an illustration showing an example of a shot order according to the first embodiment;

FIG. 16 is an illustration showing another example of a shot order according to the first embodiment;

FIG. 17 is an illustration showing another example of a shot order according to the first embodiment;

FIG. 18 is an illustration showing another example of a shot order according to the first embodiment;

FIG. 19 is a conceptual diagram showing a configuration of a writing apparatus according to a second embodiment;

FIG. 20 is a flowchart showing an example of main steps of a writing method according to the second embodiment;

FIG. 21 is an illustration showing an example of stripe regions whose respective angles in their longer directions are different from each other according to the second embodiment;

FIG. 22 is an illustration showing an example of a plurality of stripe regions whose respective angles in their longer directions are different from each other according to a third embodiment;

FIG. 23 is an illustration showing another example of a plurality of stripe regions whose respective angles in their longer directions are different from each other according to the third embodiment;

FIG. 24 is an illustration showing another example of a plurality of stripe regions whose respective angles in their longer directions are different from each other according to each of the Embodiments;

FIG. 25 is an illustration showing an example of the configuration of a deflector in each of the Embodiments;

FIG. 26 is an illustration showing another example of the configuration of the deflector in each of the Embodiments; and

FIG. 27 is an illustration showing another example of the configuration of the deflector in each of the Embodiments.

### DETAILED DESCRIPTION OF THE INVENTION

Embodiments of the present invention provide a writing apparatus and method that can perform writing with multiple different beams to a pattern edge even when a beam array which may include a defective beam is used.

Embodiments of the present invention describe a configuration using an electron beam as an example of a charged particle beam. The charged particle beam is not limited to the electron beam, and other charged particle beams such as an ion beam may also be used.

### First Embodiment

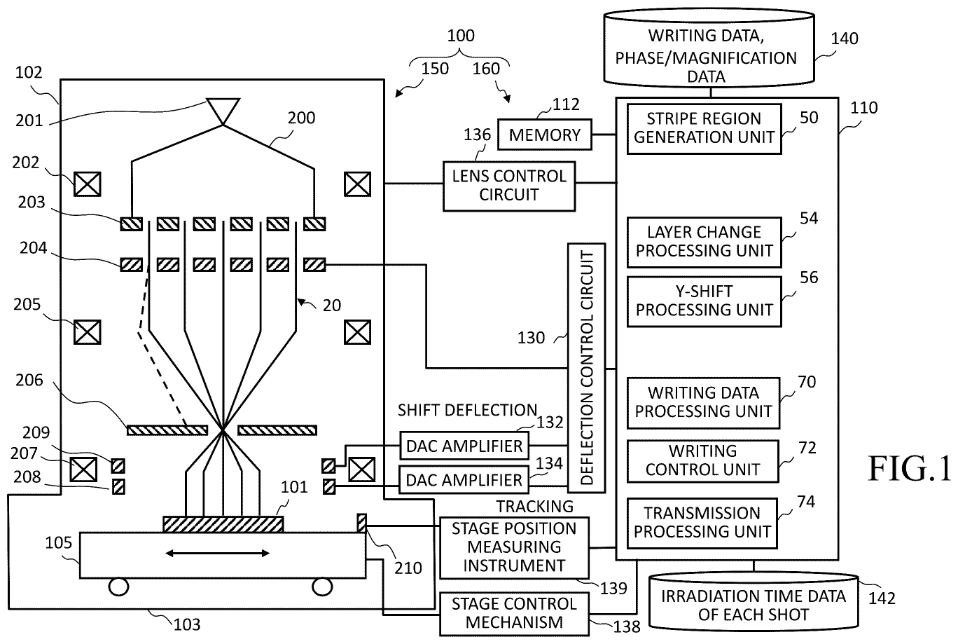

FIG. 1 is a schematic diagram showing a configuration of a writing or “drawing” apparatus according to a first embodiment. As shown in FIG. 1, a writing apparatus 100 includes a writing mechanism 150 and a control system circuit 160. The writing apparatus 100 is an example of a multi-charged particle beam writing apparatus and an example of a multi-charged particle beam exposure apparatus. The writing mechanism 150 includes an electron optical column 102 (electron beam column) and a writing chamber 103. In the electron optical column 102, there are disposed an electron source 201, an illumination lens 202, a shaping aperture array substrate 203, a blanking aperture array mechanism 204, a reducing lens 205, a limiting aperture substrate 206, an objective lens 207, a main deflector 208, and a sub deflector 209.

In the writing chamber 103, an XY stage 105 is disposed. On the XY stage 105, there is placed a target object or “sample” 101, such as a mask, serving as a writing target substrate when writing (exposure) is performed. For example, the target object 101 is an exposure mask used in fabricating semiconductor devices, or a semiconductor substrate (silicon wafer) for fabricating semiconductor devices. The target object 101 may be a mask blank on which resist has been applied and nothing has yet been written. On the XY stage 105, a mirror 210 for measuring the position of the XY stage 105 is placed.

The control system circuit 160 includes a control computer 110, a memory 112, a deflection control circuit 130, digital-analog converter (DAC) amplifier units 132 and 134, a lens control circuit 136, a stage control mechanism 138, a stage position measuring instrument 139, and storage devices 140 and 142 such as magnetic disk drives. The control computer 110, the memory 112, the deflection control circuit 130, the lens control circuit 136, the stage control mechanism 138, the stage position measuring instrument 139, and the storage devices 140 and 142 are connected to each other through a bus (not shown). The DAC amplifier units 132 and 134 and the blanking aperture array mechanism 204 are connected to the deflection control circuit 130. The sub deflector 209 is composed of at least four electrodes (or “at least four poles”), and controlled by the deflection control circuit 130 through the DAC amplifier 132 disposed for each electrode. The main deflector 208 is composed of at least four electrodes (or “at least four poles”), and controlled by the deflection control circuit 130 through the DAC amplifier 134 disposed for each electrode. Lenses, such as the illumination lens 202, the reducing lens 205, and the objective lens 207 are controlled by the lens control circuit 136.

The position of the XY stage 105 is controlled by the drive of each axis motor (not shown) which is controlled by the stage control mechanism 138. Based on the principle of laser interferometry, the stage position measurement instrument 139 measures the position of the XY stage 105 by receiving a reflected light from the mirror 210.

In the control computer 110, there are arranged a stripe region generation unit 50, a layer change processing unit 54, a Y-shift processing unit 56, a writing data processing unit 70, a writing control unit 72, and a transmission processing unit 74. Each of the “ . . . units” such as the stripe region generation unit 50, the layer change processing unit 54, the Y-shift processing unit 56, the writing data processing unit 70, the writing control unit 72, and the transmission processing unit 74 includes processing circuitry. The processing circuitry includes, for example, an electric circuit, computer, processor, circuit board, quantum circuit, semiconductor device, or the like. Each “ . . . unit” may use common processing circuitry (the same processing circuitry), or different processing circuitry (separate processing circuitry). Information input/output to/from the stripe region generation unit 50, the layer change processing unit 54, the Y-shift processing unit 56, the writing data processing unit 70, the writing control unit 72, and the transmission processing unit 74, and information being operated are stored in the memory 112 each time.

Writing operations of the writing apparatus 100 are controlled by the writing control unit 72. In other words, the writing control unit 72 (an example of a control circuit) controls the writing mechanism 150. Processing of transmitting irradiation time data of each shot to the deflection control circuit 130 is controlled by the transmission control unit 74.

Writing data (chip data) is input from the outside of the writing apparatus 100, and stored in the storage device 140. Chip data defines information on a plurality of figure patterns configuring a chip pattern. Specifically, for example, for each figure pattern, coordinates for each vertex are defined in the order of configuration of the figure. Alternatively, for example, a figure code, coordinates, a size, and the like are defined for each figure pattern.

FIG. 1 shows a configuration necessary for describing the first embodiment. Other configuration elements generally necessary for the writing apparatus 100 may also be included therein.

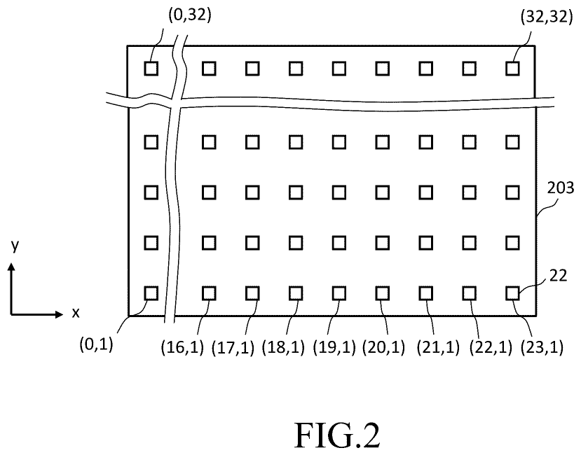

FIG. 2 is a conceptual diagram showing a configuration of a shaping aperture array substrate according to the first embodiment. As shown in FIG. 2, holes (openings) 22 of p rows long (length in the y direction) and q columns wide (width in the x direction) (p≥2, q≥2) are formed, like a matrix, at a predetermined arrangement pitch in the shaping aperture array substrate 203. In the case of FIG. 2, for example, holes 22 of 32×32, that is 32 holes in the y direction and 32 holes in the x direction, are formed. The number of the holes 22 is not limited thereto. For example, it is also preferable to form the holes 22 of 512×512. Each of the holes 22 is a rectangle (including square) having the same dimension and shape as each other. Alternatively, each of the holes 22 may be a circle with the same diameter as each other. Multiple beams 20 are formed by letting portions of an electron beam 200 individually pass through a corresponding one of a plurality of holes 22. In other words, the shaping aperture array substrate 203 forms the multiple beams 20.

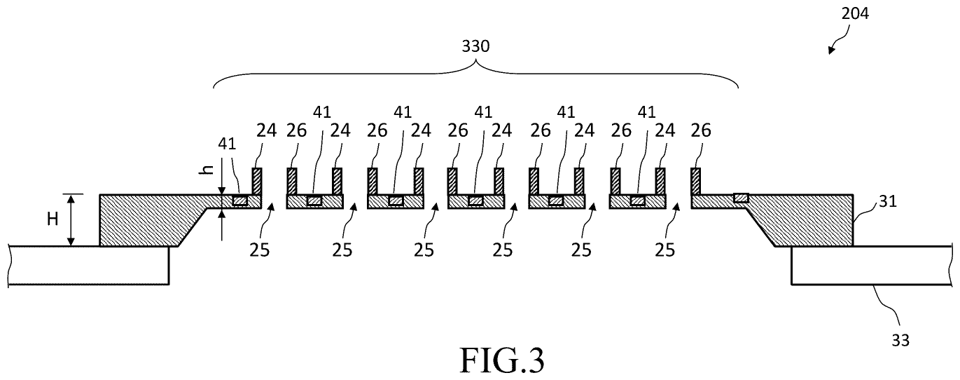

FIG. 3 is a sectional view showing a configuration of a blanking aperture array mechanism according to the first embodiment. In the blanking aperture array mechanism 204, as shown in FIG. 3, a blanking aperture array substrate 31 being a semiconductor substrate made of silicon, etc. is disposed on a support table 33. In a membrane region 330 at the center of the blanking aperture array substrate 31, a plurality of passage holes 25 (openings), through each of which a corresponding one of the multiple beams 20 passes, are formed at positions each corresponding to each hole 22 in the shaping aperture array substrate 203 shown in FIG. 2. A control electrode 24 and a counter electrode 26, being a blanker (blanking deflector), are arranged in a manner such that the electrodes 24 and 26 are opposite to each other across a corresponding one of the plurality of the passage holes 25. A control circuit 41 (logic circuit) which applies a deflection voltage to the control electrode 24 for the passage hole 25 concerned is disposed, inside the blanking aperture array substrate 31, close to each corresponding passage hole 25. The counter electrode 26 for each beam is grounded.

In the control circuit 41, an amplifier (not shown) (an example of a switching circuit) is arranged. As an example of the amplifier, a CMOS (Complementary MOS) inverter circuit serving as a switching circuit is disposed. With regard to inputs (IN) to the CMOS inverter circuit, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the CMOS inverter circuit, the output (OUT) of the CMOS inverter circuit, which is to be applied to the control circuit 41, becomes a positive potential (Vdd), and then, a corresponding beam is deflected by an electric field due to a potential difference from the ground potential of the counter electrode 26, and is controlled to be in a beam-off condition by being blocked by the limiting aperture substrate 206. In contrast, in a state (active state) where an H potential is applied to the input (IN) of the CMOS inverter circuit, the output (OUT) of the CMOS inverter circuit becomes a ground potential, and therefore, since there is no potential difference from the ground potential of the counter electrode 26, a corresponding beam is not deflected, and is controlled to be in a beam-on condition by passing through the limiting aperture substrate 206. Blanking control is provided by such deflection.

Next, operations of the writing mechanism 150 will be described. The electron beam 200 emitted from the electron source 201 (emission source) almost perpendicularly (e.g., vertically) illuminates the whole of the shaping aperture array substrate 203 by the illumination lens 202. A plurality of rectangular holes 22 (openings) are formed in the shaping aperture array substrate 203. The region including all of the plurality of holes 22 is irradiated with the electron beam 200. For example, rectangular multiple beams (a plurality of electron beams) 20 are formed by letting portions of the electron beam 200 applied to the positions of the plurality of holes 22 individually pass through a corresponding one of the plurality of holes 22 in the shaping aperture array substrate 203. The multiple beams 20 individually pass through corresponding blankers of the blanking aperture array mechanism 204. The blanker provides blanking control such that a corresponding beam individually passing becomes in an ON condition during a set writing time (irradiation time).

The multiple beams 20 having passed through the blanking aperture array mechanism 204 are reduced by the reducing lens 205, and travel toward the hole in the center of the limiting aperture substrate 206. The electron beam which was deflected by the blanker of the blanking aperture array mechanism 204 deviates from the hole in the center of the limiting aperture substrate 206 and is blocked by the limiting aperture substrate 206. In contrast, the electron beam which was not deflected by the blanker of the blanking aperture array mechanism 204 passes through the hole in the center of the limiting aperture substrate 206 as shown in FIG. 1. Thus, the limiting aperture substrate 206 blocks each beam which was deflected to be in an OFF state by the blanker of the blanking aperture array mechanism 204. Then, each beam for one shot of the multiple beams 20 is formed by a beam which has been made during a period from becoming beam-on to becoming beam-off and has passed through the limiting aperture substrate 206. The multiple beams 20 having passed through the limiting aperture substrate 206 are focused by the objective lens 207 so as to be a pattern image of a desired reduction ratio. Then, all of the multiple beams 20 having passed through the limiting aperture substrate 206 are collectively deflected in the same direction by the main deflector 208 and the sub deflector 209 in order to irradiate respective beam irradiation positions on the target object 101. For example, when the XY stage 105 is continuously moving, tracking control is performed by the main deflector 208 so that the beam irradiation position may follow the movement of the XY stage 105. Ideally, the multiple beams 20 irradiating at a time are aligned at a pitch obtained by multiplying the arrangement pitch of a plurality of holes 22 in the shaping aperture array substrate 203 by the desired reduction ratio described above.

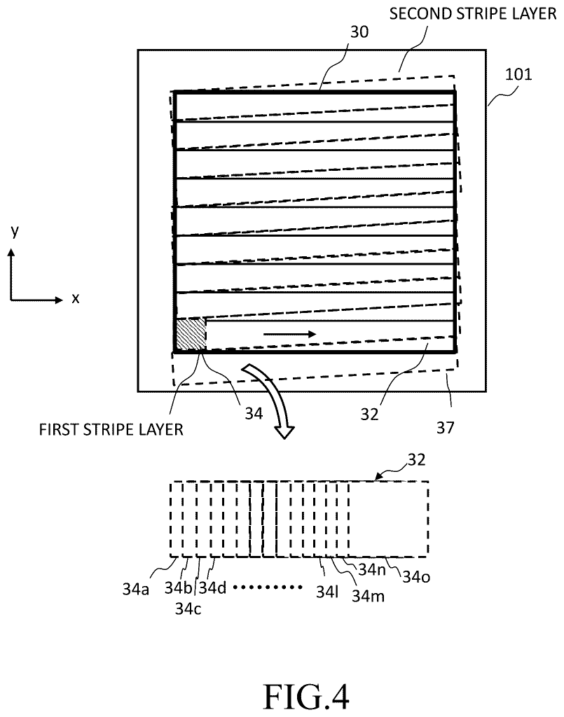

FIG. 4 is a conceptual diagram for explaining an example of a writing region and a stripe region according to the first embodiment. As shown in FIG. 4, a writing region 30 (bold line) of the target object 101 is virtually divided into a plurality of stripe regions 32 by a predetermined width in the y direction, for example. In the case of FIG. 4, the writing region 30 of the target object 101 is divided in the y direction, for example, into a plurality of stripe regions 32 by the width size being substantially the same as the design size of an irradiation region 34 (writing field) that can be irradiated with one irradiation of the multiple beams 20. The dividing direction is not limited to the y direction.

FIG. 4 shows the case of performing multiple writing with multiplicity 2, for example. For the first writing processing of the multiple writing processing, the first stripe layer composed of a plurality of stripe regions 32 obtained by dividing the writing region 30 is set. For the second writing processing of the multiple writing processing, the second stripe layer is set to be composed of a plurality of stripe regions 37 whose angle in the longer direction is different from that in the longer direction of a corresponding stripe region 32 in the first stripe layer. Let the stripe regions 32 and 37 of the first and second stripe layers whose some regions are overlapped with each other be one group. The multiplicity is not limited to 2, it may be 3 or more. Expressed in another way, the stripe layers is not limited to two such as the first and second stripe layers, and may be three or more. What is necessary is that respective angles in their longer directions of the stripe layers are different from each other.

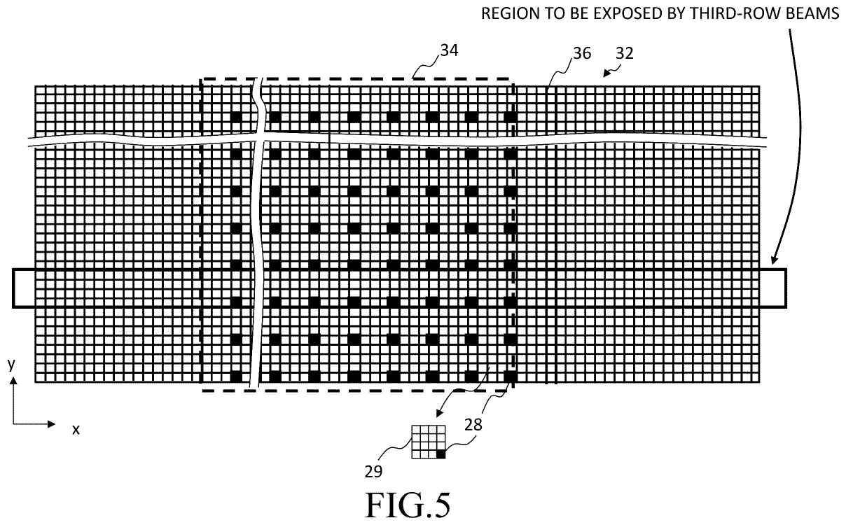

FIG. 5 is an illustration of an example of an irradiation region of multiple beams and a pixel to be written (writing target pixel) according to the first embodiment. FIG. 5 shows the stripe region 32, as an example, in the state where the angle in the longer direction of a plurality of the stripe regions 32 is different from that of a plurality of the stripe regions 37. The stripe region 37 is the same as the stripe region 32 except that the angle in the longer direction of the stripe region 37 is inclined relative to that of the stripe region 32. In FIG. 5, the stripe region 32 is divided into a plurality of mesh regions by the beam size of each of the multiple beams 20, for example. Each mesh region serves as a writing target pixel 36 (beam irradiation unit region, irradiation region). The size of the writing target pixel 36 is not limited to the beam size, and may be any size regardless of beam size. For example, it may be 1/n (n being an integer of 1 or more) of the beam size. FIG. 5 shows the case where the writing region on the target object 101 is divided, for example, in the y direction, into a plurality of stripe regions 32 by the width size being substantially the same as the size of the irradiation region 34 (writing field) that can be irradiated with one irradiation of the multiple beams 20. The x-direction size of the rectangular, including square, irradiation region 34 can be defined by (the number of x-direction beams)×(x-direction beam pitch). The y-direction size of the rectangular irradiation region 34 can be defined by (the number of y-direction beams)×(y-direction beam pitch). FIG. 5 shows the case of multiple beams of 32×32 (rows×columns) having been simplified to 8×8 (rows×columns). In the irradiation region 34, there are shown a plurality of pixels 28 (beam writing positions) which can be irradiated with one shot of the multiple beams 20. The pitch between adjacent pixels 28 is the beam pitch (pitch between beams) of the multiple beams. A sub-irradiation region 29 (pitch cell region) is configured by a rectangular, including square, region surrounded by the size of beam pitches in the x and y directions. In the example of FIG. 5, each sub-irradiation region 29 is composed of 4×4 pixels, for example.

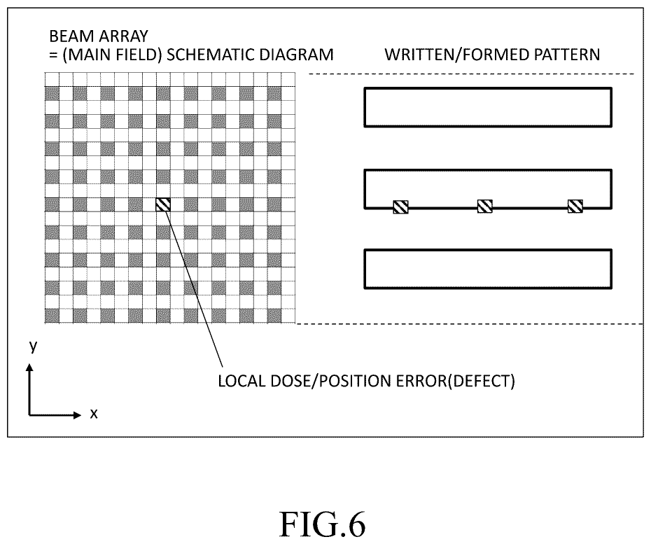

FIG. 6 is an illustration of an example of beam arrays and written patterns according to a comparative example 1 of the first embodiment. FIG. 6 shows the case where the center beam in beam arrays of 9×9 rows and columns is an ON defective beam whose dose is difficult to control. For example, when one of the arrangement directions of a beam array and the longer direction of a stripe region are both x directions, if a pattern whose side being a pattern edge is in the x direction is written, a plurality of pixels written with the defective beam are periodically located in a line on the pattern edge as shown in FIG. 6. As a result, cyclic pattern dimension errors and/or pattern errors occur.

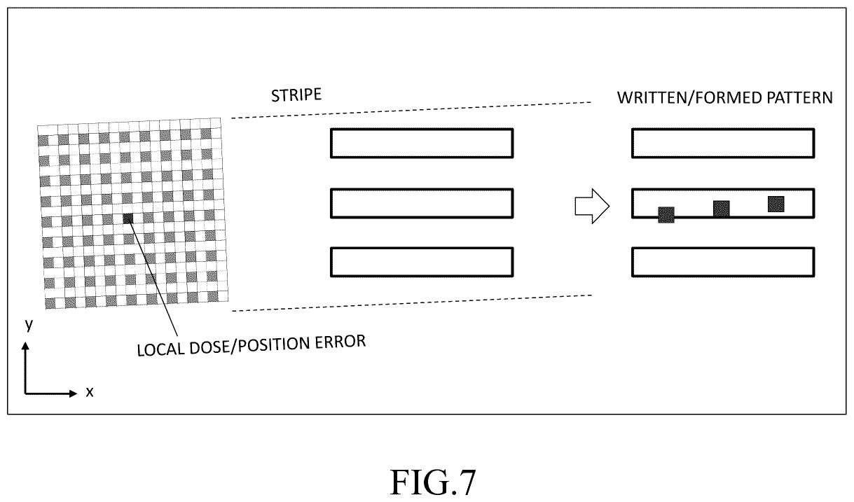

FIG. 7 is an illustration of an example of beam arrays and written patterns according to a comparative example 2 of the first embodiment. In FIG. 7, writing is performed in the case where the direction of an exposure stripe is inclined relative to the direction of the pattern edge. By this, as shown in FIG. 7, the number of defective beams applied on the pattern edge can be reduced. However, as described above, it is not easy for the writing apparatus to know/obtain directions of pattern edges. An enormous amount of calculation processing is needed for obtaining the directions of all the pattern edges.

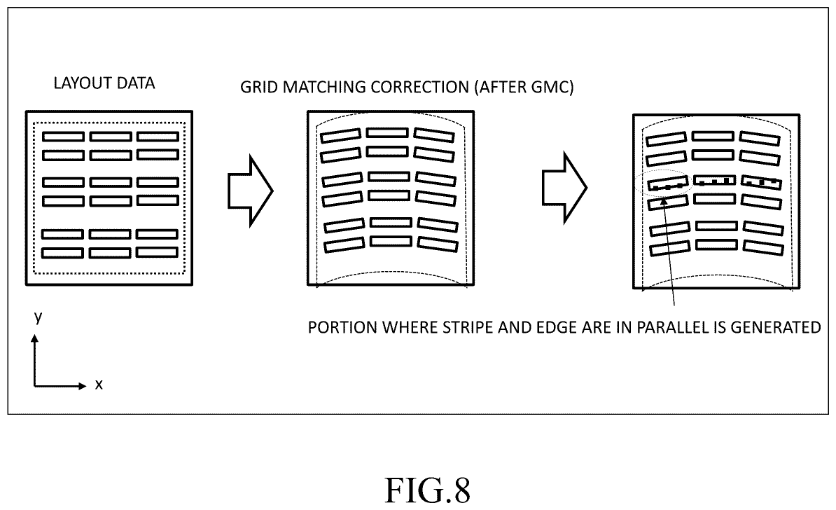

FIG. 8 is an illustration of examples of a pattern layout before and after grid matching correction according to a comparative example 3 of the first embodiment. In electron beam writing, since deviation of an irradiation position due to the influence of the optical system and the like may occur in both the cases of using a single beam and multiple beams, there is a case of performing grid matching correction to correct the deviation so as to achieve the writing. In that case, in a pattern layout in the writing data, even when the pattern edge direction is in the x direction, for example, the pattern edge direction may change at least some patterns because of the grid matching correction. Therefore, as explained referring to FIG. 7, even if writing is performed in an oblique direction, consequently, defective beams may be periodically applied in parallel to the pattern edge.

Thus, in the first embodiment, multiple writing based on writing processing in a plurality of writing directions is performed. The following provides a more detailed description.

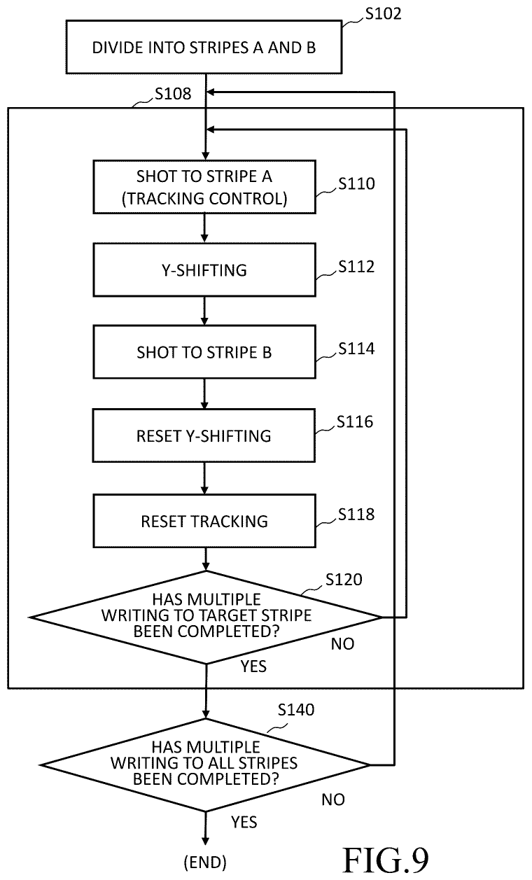

FIG. 9 is a flowchart showing an example of main steps of a writing method according to the first embodiment. In FIG. 9, the writing method of the first embodiment executes a series of steps: a stripes A and B generation step (S102), a multiple writing step (S108), and a determination step (S140). As internal steps of the multiple writing step (S108), there are performed a stripe A shot (tracking control) step (S110), a Y-shifting step (S112), a stripe B shot step (S114), a Y-shifting reset step (S116), a tracking reset step (S118), and a determination step (S120).

In the stripes A and B generation step (S102), the stripe region generation unit 50 generates a plurality of stripe regions 32 (the first stripe regions) by dividing the writing region 30 of the target object 101 (substrate) such that the longer direction of each of the plurality of stripe regions 32 is in the x direction (the first direction), and a plurality of stripe regions 37 (the second stripe regions) being divided such that the longer direction of each of the plurality of stripe regions 37 is in the direction (the second direction) having a predetermined relative angle to the x direction. In other words, the stripe region generation unit 50 divides the writing region 30 of the target object 101 (substrate) to generate a plurality of stripe regions 32 (the first stripe region) by dividing in the y direction, for example, and generate a plurality of stripe regions 37 (the second stripe region) whose longer direction has a relative angle (not being 0 degrees) to that of the plurality of stripe regions 32. Let the first and second stripe regions whose some portions are overlapped with each other be one group.

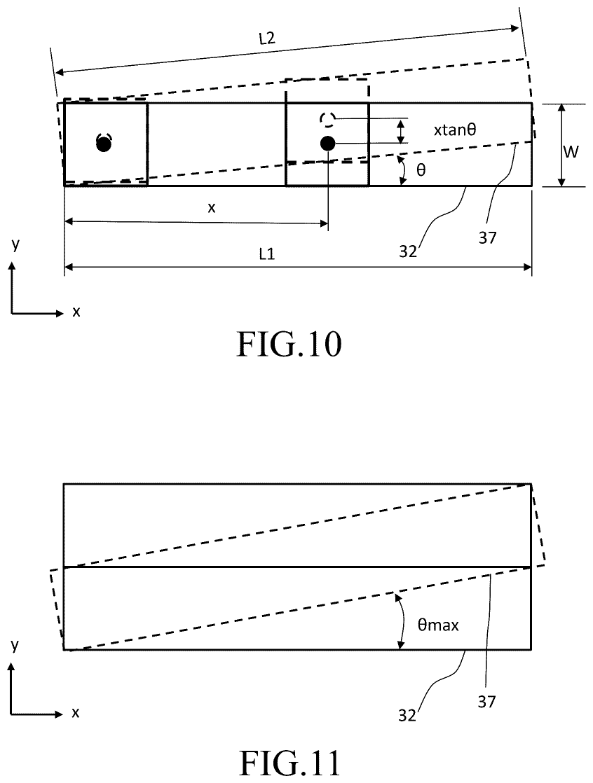

FIG. 10 is an illustration showing an example of stripe regions whose respective angles in their longer directions are different from each other according to the first embodiment. FIG. 10 shows the stripe region 32 whose longer direction is in the x direction, and the rectangular stripe region 37 whose longer direction has the angle θ with respect to the x direction. The positions of the lower left corners of the stripe regions 32 and 37 are the same (common). Expressed in another way, the stripe region 37 is rotated by the angle θ using the lower left corner of the stripe region 32 as a fulcrum. Some portions are overlapped with each other in the stripe regions 32 and 37. The stripe region 37 is set to have a length L2 such that at least the upper right corner of the stripe region 32 is included in the stripe region 37. Therefore, preferably, the length L2 of the stripe region 37 is set to be longer than the length L1 of the stripe region 32. The widths W of the stripe regions 32 and 37 are the same size as each other.

FIG. 11 is an illustration showing an example of the maximum relative angle between stripe regions whose respective angles in their longer directions are different from each other according to the first embodiment. The maximum relative angle θmax being the maximum of the relative angle θ between the stripe regions 32 and 37 is defined by W/L1. Therefore, θ satisfies the following equations (1).

0<θ≤W/L1 (1)

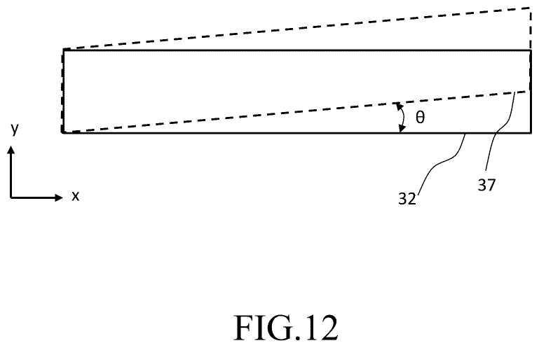

FIG. 12 is an illustration showing another example of a plurality of stripe regions whose respective angles in their longer directions are different from each other according to the first embodiment. FIG. 12 shows the rectangular stripe region 32 and the parallelogram stripe region 37 whose longer direction has a relative angle θ to the longer direction of the stripe region 32. The side in the shorter direction of the parallelogram stripe region 37 is coincided with that of the rectangular stripe region 32. This makes it possible for the stripe region 37 not to include an excessive region being out of the writing region 30.

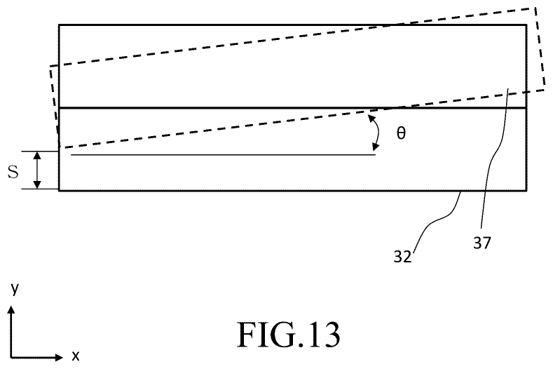

FIG. 13 is an illustration showing another example of a plurality of stripe regions whose respective angles in their longer directions are different from each other according to the first embodiment. In FIG. 13, each of a plurality of stripe regions 37 is generated by offsetting (shifting) its reference position with respect to the stripe region 32 in the same group. Expressed in another way, a plurality of stripe regions 37 are generated at the positions each obtained by offsetting the reference position (for example, lower left of the stripe region) by a distance “s” in the y direction with respect to the corresponding stripe region 32. FIG. 13 shows the case where the stripe region 37 shown in FIG. 9 is generated at the position shifted by the distance “s” in the y direction from the stripe region 32. In FIG. 13, there are shown one of a plurality of stripe regions 32 and one of a plurality of stripe regions 37. Although here the upper right corner of the corresponding stripe region 32 is not included in the stripe region 37 concerned, that upper right corner of the stripe region 32 is to be included in another stripe region 37 (not shown) being adjacent in the −y direction.

In the multiple writing step (S108), the writing mechanism 150 repeats tracking control so that the irradiation region 34 of the multiple beams 20 may follow the movement of the XY stage 105. Furthermore, during each of the tracking controls, regarding, as a group, the stripe region 32 of a plurality of stripe regions 32 and the stripe region 37 of a plurality of stripe regions 37 where some regions of the stripe region 32 and the stripe region 37 are overlapped with each other, the writing mechanism 150 performs writing to the group of the stripe regions 32 and 37 while moving the irradiation region 34 of the multiple beams 20 between the stripe regions 32 and 37 in the same group during one movement of the stage in the writing direction. In other words, the writing mechanism 150 repeats tracking control so that the irradiation region 34 of the multiple beams 20 may follow the movement of the XY stage 105. Furthermore, during each of the tracking controls, the writing mechanism 150 performs controlling such that the irradiation region 34 of the multiple beams 20 moves between the stripe regions 32 and 37 in a group, where the relative angle between their longer directions is the angle θ, in the plurality of stripe regions 32 and 37. Furthermore, the writing mechanism 150 performs writing to the group of the stripe regions 32 and 37 while moving the irradiation region 34 of the multiple beams 20 between the stripe regions 32 and 37 during one movement of the stage in the direction (−x direction) parallel to the x direction (writing direction) which is perpendicular to the y direction to move the writing in the writing direction. Next, an example of a writing operation is described.

First, the XY stage 105 is moved to make an adjustment such that the irradiation region 34 of the multiple beams 20 is located at the left end, or at a position further left than the left end, of the first stripe region 32 of the first stripe layer shown in FIG. 4. When writing the first stripe region 32, the XY stage 105 is moved, for example, in the −x direction, so that the writing may proceed relatively in the x direction. The XY stage 105 is moved continuously at a constant speed, for example. According to the first embodiment, during one movement (one pass) in the −x direction of the XY stage 105, writing is performed to all the first stripe regions 32 and 37 in each stripe layer.

Specifically, during the same tracking control (one tracking control), a shot to the stripe region 32 and a shot to the stripe region 37 are performed. As shown in FIG. 10, when shifting a shot from that to the stripe region 32 to that to the stripe region 37, beam deflection (Y-shifting) of all the multiple beams 20 is performed in the y direction such that the center of the multiple beams 20 is shifted from the y-direction center position of the stripe region 32 to that of the stripe region 37. For example, after at least one shot to the stripe region 32 is completed, a Y-shifting is carried out to perform at least one shot to the stripe region 37. Then, tracking reset is executed to proceed to the next tracking control. By repeating this operation, writing to the first stripe regions 32 and 37 is performed.

After writing to the first stripe region 32 of each stripe layer, the stage position is moved in the −y direction by the width size of the stripe region 32. Thereby, the stripe region 32 to be written is shifted (displaced) in the y direction by the width size of the stripe region 32.

Next, an adjustment is made so that the irradiation region 34 of the multiple beams 20 can be located at the left end, or at a position further left than the left end, of the second stripe region 32 of the first stripe layer. By moving the XY stage 105 in the −x direction, for example, writing proceeds relatively in the x direction. Thereby, writing is performed to the second stripe regions 32 and 37 of each stripe layer. In this way, during one movement (one pass) in the −x direction of the XY stage 105, the corresponding stripe regions 32 and 37 in each stripe layer are written. Henceforth, by repeating similar operations, writing to all the stripe regions 32 and 37 in each stripe layer is performed. The switching (changing) of the stripe layer in each pass is carried out by Y deflection (Y-shifting) by the main deflector 208 described later. Thereby, multiple writing is performed to the region where the stripe regions 32 and 37 are overlapped with each other in each stripe layer.

Owing to one shot of multiple beams having been formed by individually passing through the holes 22 in the shaping aperture array substrate 203, a plurality of shot patterns up to the number of the holes 22 are maximally formed at a time.

The following provides a more detailed description.

In the stripe A shot (tracking control) step (S110), while performing a tracking control, the writing mechanism 150 applies shots of the multiple beams 20 to a plurality of pixels 36 in the stripe region 32 (stripe A) located in the irradiation region 34 of the multiple beams 20.

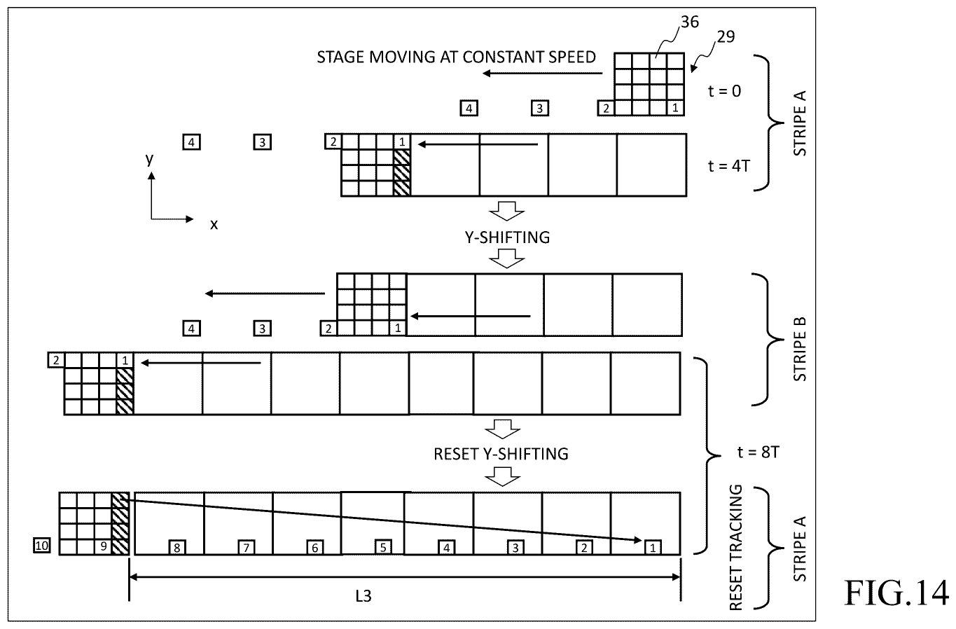

FIG. 14 is an illustration for explaining an example of a multiple beam writing operation according to the first embodiment. FIG. 14 shows the case where the inside of each sub-irradiation region 29 is written with four different beams. Furthermore, the example of FIG. 14 shows a writing operation where, during a ¼ region namely the region of 1/(the number of beams used for irradiation) in each sub-irradiation region 29 being written, the XY stage 105 continuously moves at the speed at which it moves the distance L of four beam pitches. In the writing operation shown in FIG. 14, for example, while the XY stage 105 moves the distance of four beam pitches ((L3)/2 ), different four pixels in the same sub-irradiation region 29 are written (exposed) by applying four shots of the multiple beams 20 at a shot cycle T to the sub-irradiation region 29 in the stripe region 32 with shifting the irradiation position (pixel 36) in order by the sub deflector 209. In order that the relative position between the irradiation region 34 and the target object 101 may not be shifted by the movement of the XY stage 105 while these four pixels 36 are written (exposed), the irradiation region 34 is made to follow the movement of the XY stage 105 by collective deflection of all of the multiple beams 20 by the main deflector 208. In other words, a tracking control is performed.

In the Y-shifting step (S112), after applying four shots to the sub irradiation region 29 in the stripe region 32 during the same tracking control (one tracking control), the layer change processing unit 54 controls the main deflector 208 to shift the irradiation region 34 of the multiple beams 20 into the stripe region 37 by performing beam deflection, in the y direction, of the irradiation region 34. As shown in FIG. 10, when a shot to the stripe region 32 is changed to a shot to the stripe region 37, the center of the multiple beams 20 is shifted (Y-shifting) from the y-direction center position of the stripe region 32 to the y-direction center position of the stripe region 37. At this time, the shift amount in the y direction changes depending on a distance x from the left end (writing starting side end) of the stripe region 32. Specifically, as shown in FIG. 10, the shift amount of Y-shifting is defined by xtanθ.

In the stripe B shot step (S114), while continuously performing tracking control, the writing mechanism 150 applies shots of the multiple beams 20 to a plurality of pixels 36 in the stripe region 37 (stripe B) located in the irradiation region 34 of the multiple beams 20. In FIG. 14, for example, while the XY stage 105 moves the distance of four beam pitches ((L3)/2), different four pixels in the same sub-irradiation region 29 are written (exposed) by applying four shots of the multiple beams 20 at the shot cycle T to the sub-irradiation region 29 in the stripe region 32 with shifting the irradiation position (pixel 36) in order by the sub deflector 209. In order that the relative position between the irradiation region 34 and the target object 101 may not be shifted by the movement of the XY stage 105 while these four pixels 36 are written (exposed), the irradiation region 34 is made to follow the movement of the XY stage 105 by collective deflection of all of the multiple beams 20 by the main deflector 208. In other words, a tracking control is performed.

In the Y-shifting reset step (S116), after applying four shots to the sub irradiation region 29 in the stripe region 37, the layer change processing unit 54 controls the main deflector 208 to return the irradiation region 34 of the multiple beams 20 into the stripe region 32 by resetting the beam deflection which deflects, in the y direction, the irradiation region 34 of the multiple beams 20 (that is, beam deflection is performed in the −y direction).

In the tracking reset step (S118), after one tracking cycle is completed, the writing control unit 72 resets tracking to return to the previous (last) tracking start position. Since writing of the pixels in the first column from the right of each sub-irradiation region 29 has been completed, in the next tracking cycle after resetting the tracking, first, the sub deflector 209 provides deflection such that the writing position of a beam is adjusted (shifted) to write the second pixel column from the right still not having been written in each sub-irradiation region 29, for example.

In the determination step (S120), the writing control unit 72 determines whether multiple writing of a target stripe region has been completed. If the multiple writing of the target stripe region has been completed, it proceeds to the determination step (S140). If not completed, it returns to the stripe A shot (tracking control) step (S110), and repeats each step from the stripe A shot (tracking control) step (S110) to the determination step (S120) until the multiple writing of the target stripe region has been completed.

Thus, by repeating this operation during writing the stripe regions 32 and 37, as shown in the lower part of FIG. 4, the position of the irradiation region 34 of the multiple beams 20 is sequentially moved (shifted), such as the irradiation region from 34a, 34b, 34c, . . . to 34o, to perform writing in the target stripe regions 32 and 37 in each stripe layer.

In the determination step (S140), the writing control unit 72 determines whether multiple writing of all the stripe regions has been completed. If multiple writing of all the stripe regions has not been completed, it returns to the multiple writing step (S108), and repeats the multiple writing step (S108), while moving the target stripe region one by one, until the multiple writing of all the stripe regions has been completed. When multiple writing all the stripe regions has been completed, the writing processing is finished.

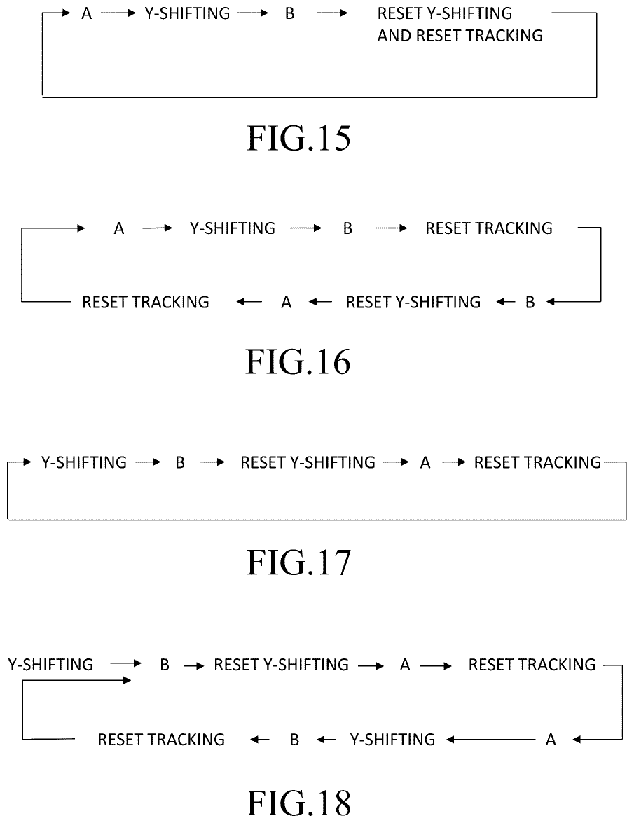

FIG. 15 is an illustration showing an example of a shot order according to the first embodiment. In FIG. 15, as explained in the example of FIG. 14, after applying a shot to the stripe region A (stripe region 32), Y-shifting is performed so as to apply a shot to the stripe region B (stripe region 37). Then, after the shot to the stripe region B (stripe region 37), Y-shifting reset and tracking reset are performed. The shot order is not limited thereto.

FIG. 16 is an illustration showing another example of a shot order according to the first embodiment. In FIG. 16, after applying a shot to the stripe region A (stripe region 32), Y-shifting is performed so as to apply a shot to the stripe region B (stripe region 37). Then, while continuing the Y-shift, tracking reset is performed. In the next tracking control, after applying a shot to the stripe region B (stripe region 37), Y-shifting reset is performed so as to applying a shot to the stripe region A (stripe region 32). Then, tracking reset is performed. In the next tracking control, applying a shot to the stripe region A (stripe region 32) is first performed. Thus, it is also preferable to apply a shot to the same stripe region before and after the tracking reset.

FIG. 17 is an illustration showing another example of a shot order according to the first embodiment. In FIG. 17, first, Y-shifting is performed, and then, a shot is applied to the stripe region B (stripe region 37). Next, Y-shifting reset is performed so as to apply a shot to the stripe region A (stripe region 32), and then, tracking reset is performed. Thus, it is also preferable to first apply a shot to an oblique stripe region side.

FIG. 18 is an illustration showing another example of a shot order according to the first embodiment. In FIG. 18, first, Y-shifting is performed, and then, a shot is applied to the stripe region B (stripe region 37). Then, Y-shifting reset is performed so as to apply a shot to the stripe region A (stripe region 32), and then, tracking reset is performed. In the next tracking control, after applying a shot to the stripe region A (stripe region 32), Y-shifting is performed so as to apply a shot to the stripe region B (stripe region 37). Then, tracking reset is performed. In the next tracking control, since it is in the state where Y-shifting has already been carried out, a shot is applied to the stripe region B (stripe region 37). Thus, it is also preferable, while first applying a shot to the oblique stripe region side, to perform applying a shot to the same stripe region before and after the tracking reset.

In the examples of FIGS. 15 to 18, at the time of a shot to the stripe region in each stripe layer, at least one-time shot is performed. Furthermore, although it is desirable that the numbers of times of shots to the stripe regions in respective stripe layers during the same tracking control (one tracking control) are the same with each other, it is not limited thereto. Different numbers of times are also acceptable. By switching the numbers of times of shots for respective tracking controls, writing processing without any missing can be performed.

As described above, according to the first embodiment, multiple writing is performed, during one stage movement (during one pass), to a plurality of stripe regions 32 and 37 where their relative angle is θ. Thereby, it becomes possible to perform writing with at least several different beams to a pattern edge which is included in writing of patterns in any chip layout, without increasing the stage turning time. Furthermore, it is possible to reduce that a local dose error in a beam array is applied n times repeatedly to a pattern, to 1/n times. Furthermore, the multiplicity in the stripe region can be increased without changing the number of times of the stage movement. Therefore, compared to the case of increasing, with the same multiplicity, the number of passes, it is possible to prevent damage to stage parts. Thus, the life of the stage can be improved, and the downtime due to regular replacement of parts can be reduced.

Thus, according to the first embodiment, even when a beam array which may include a defective beam is used, writing with multiple different beams can be performed to a pattern edge.

### Second Embodiment

In the above first embodiment, the case is described where the arrangement direction (x direction) of a beam array is different from the longer direction of the stripe region 37 which has a relative angle θ to the arrangement direction (x direction). However, it is not limited thereto. The contents of a second embodiment are the same as those of the first embodiment except for what is particularly described below.

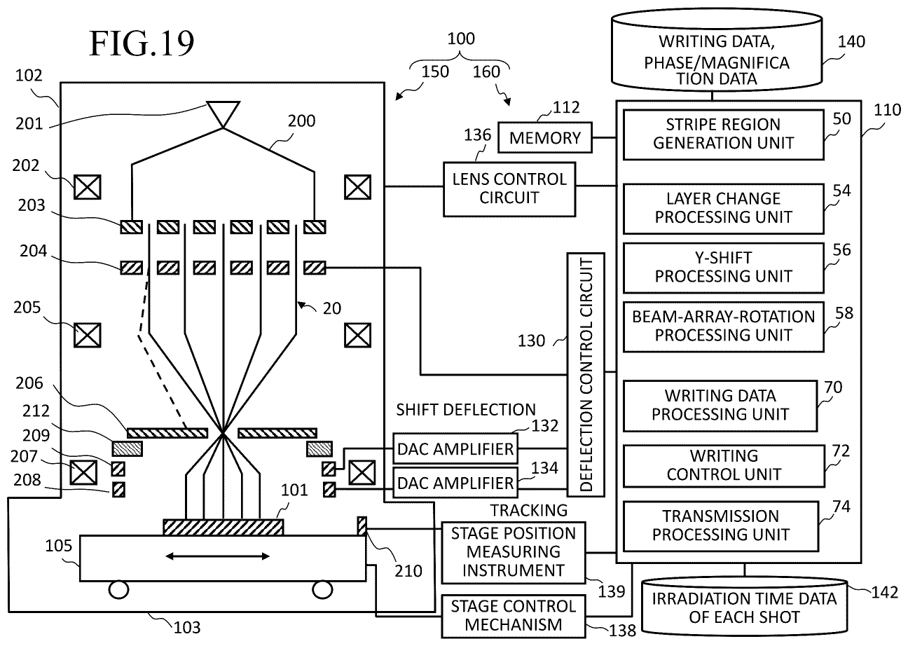

FIG. 19 is a conceptual diagram showing a configuration of a writing apparatus according to the second embodiment. FIG. 19 is the same as FIG. 1 except that an electrostatic lens 212, and a beam-array-rotation processing unit 58 is added in the control computer 110.

The electrostatic lens 212 is controlled by the deflection control circuit 130 or an electrostatic lens control circuit (not shown). The electrostatic lens 212 is composed of, for example, three stages of electrode substrates each where an opening through which multiple beams 20 can pass is formed at the center. A ground (GND) potential is applied to the first and third electrode substrates, and a control potential is applied to the second electrode substrate, thereby producing a lens effect. As a lens effect, there is rotation and/or focus position control, for example. The number of stages of the electrode substrates is not limited to three, and what is essential is there being two or more ones. In the case of FIG. 19, the electrostatic lens 212 is arranged between the limiting aperture substrate 206 and the sub deflector 209, however, it is not limited thereto. The electrostatic lens 212 should be arranged at the position on which it can make an image of the multiple beams 20 rotate.

Each of the “ . . . units” such as the stripe region generation unit 50, the layer change processing unit 54, the Y-shift processing unit 56, the beam-array-rotation processing unit 58, the writing data processing unit 70, the writing control unit 72, and the transmission processing unit 74 includes processing circuitry. The processing circuitry includes, for example, an electric circuit, computer, processor, circuit board, quantum circuit, semiconductor device, or the like. Each “ . . . unit” may use common processing circuitry (the same processing circuitry), or different processing circuitry (separate processing circuitry). Information input/output to/from the stripe region generation unit 50, the layer change processing unit 54, the Y-shift processing unit 56, the beam-array-rotation processing unit 58, the writing data processing unit 70, the writing control unit 72, and the transmission processing unit 74, and information being operated are stored in the memory 112 each time.

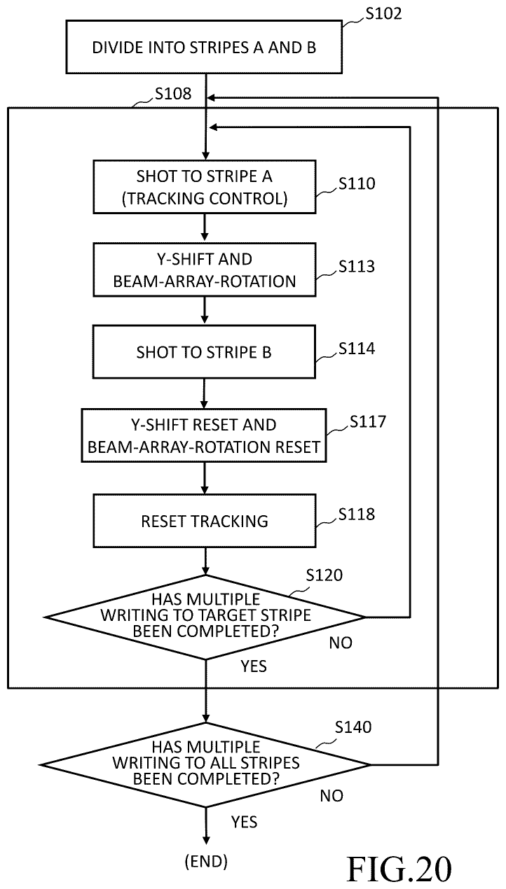

FIG. 20 is a flowchart showing an example of main steps of a writing method according to the second embodiment. FIG. 20 is the same as FIG. 9 except that a Y-shift & beam-array-rotation step (S113) is executed instead of the Y-shifting step (S112), and a Y-shift reset & beam-array-rotation reset step (S117) is executed instead of the Y-shifting reset step (S116).

The contents of the stripes A and B generation step (S102) are the same as those of the first embodiment.

In the multiple writing step (S108), the writing mechanism 150 repeats tracking control so that the irradiation region 34 of the multiple beams 20 may follow the movement of the XY stage 105. Furthermore, during each of the tracking controls, the writing mechanism 150 performs controlling such that the irradiation region 34 of the multiple beams 20 moves between the stripe regions 32 and 37 being corresponding to each other and having the relative angle θ between their longer directions. Furthermore, the writing mechanism 150 performs writing to the stripe regions 32 and 37 being corresponding to each other while moving the irradiation region 34 of the multiple beams 20 between the stripe regions 32 and 37 during one movement of the stage in the −x direction, for example. At this process, when performing writing to a plurality of stripe regions 37, the electron lens 212 (an example of an optical mechanism) rotates, according to the relative angle θ, the irradiation region 34 of the multiple beams 20 at the time of performing writing to a plurality of stripe regions 32. The following provides a more detailed description.

The contents of the stripe A shot (tracking control) step (S110) are the same as those of the first embodiment.

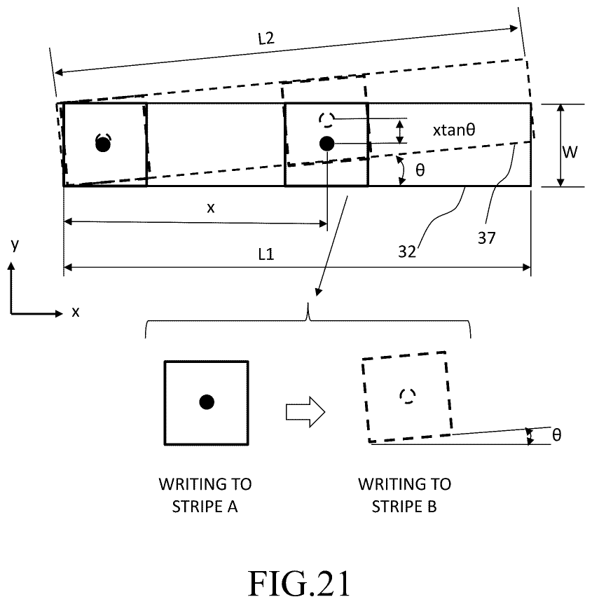

FIG. 21 is an illustration showing an example of stripe regions whose respective angles in their longer directions are different from each other according to the second embodiment. FIG. 21 shows the stripe region 32 and the stripe region 37 which are the same as those of FIG. 10. Similarly to the first embodiment, the stripe region 37 is rotated by the angle θ using the lower left corner of the stripe region 32 as a fulcrum. Some portions are overlapped with each other in the stripe regions 32 and 37. The stripe region 37 is set to have a length L2 such that at least the upper right corner of the stripe region 32 is included in the stripe region 37. Therefore, preferably, the length L2 of the stripe region 37 is set to be longer than the length L1 of the stripe region 32. The widths W of the stripe regions 32 and 37 are the same size as each other.

In the Y-shift & beam-array-rotation step (S113), after applying four shots to the sub irradiation region 29 in the stripe region 32 during the same tracking control (one tracking control), the layer change processing unit 54 controls the main deflector 208 to shift the irradiation region 34 of the multiple beams 20 into the stripe region 37 by performing beam deflection, in the y direction, of the irradiation region 34. As shown in FIG. 21, when a shot to the stripe region 32 is changed to a shot to the stripe region 37, the center of the multiple beams 20 is shifted (Y-shifting) from the y-direction center position of the stripe region 32 to the y-direction center position of the stripe region 37. At this time, the shift amount in the y direction changes depending on a distance x from the left end (writing starting side end) of the stripe region 32. Specifically, as shown in FIG. 21, the shift amount of Y-shifting is defined by xtanθ.

Furthermore, the irradiation region 34 of the multiple beams 20 is rotated by the electrostatic lens 212 according to the relative angle θ. By this, the direction of the irradiation region 34 of the multiple beams 20 can be suited to the stripe region 37. Thus, when next writing the stripe region 37, the irradiation region 34 (beam array region) of the multiple beams 20 does not go out of the stripe region 37 and no beam exists that does not irradiate the stripe region 37. Thereby, writing can be performed without any waste. As a result, writing efficiency can be increased.

The contents of the stripe B shot step (S114) are the same as those of the first embodiment.

In the Y-shift reset & beam-array-rotation reset step (S117), after applying four shots to the sub irradiation region 29 in the stripe region 37, the layer change processing unit 54 controls the main deflector 208 to return the irradiation region 34 of the multiple beams 20 into the stripe region 32 by resetting the beam deflection which deflects, in the y direction, the irradiation region 34 of the multiple beams 20 (that is, beam deflection is performed in the −y direction).

At this time, the electrostatic lens 212 resets the rotation of the irradiation region 34 of the multiple beams 20. By this, the direction of the irradiation region 34 of the multiple beams 20 can be suited to the stripe region 32. Thus, when next writing the stripe region 32, the irradiation region 34 (beam array region) of the multiple beams 20 does not go out of the stripe region 32 and no beam exists that does not irradiate the stripe region 32. Thereby, writing can be performed without any waste.

The contents of each of the tracking reset step (S118) and the determination step (S120) are the same as those of the first embodiment.

As described above, according to the second embodiment, in addition to the effect of the first embodiment, writing can be performed without any waste.

### Third Embodiment

In each of the above Embodiments, the case has been described where one stripe region 32 and one stripe region 37, being corresponding to each other, whose respective relative angles not being zero are different from each other are generated. However, it is not limited thereto. The stripe regions 32 and 37 may have a one-to-many relationship. A third embodiment describes the case where stripe regions having a one-to-many relationship in which one stripe region corresponds to many stripe regions are generated. The configuration of the writing apparatus 100 in the third embodiment is the same as that of FIG. 1 or 19. The flowchart showing an example of main steps of the writing method according to the third embodiment is the same as that of FIG. 9 or 20. The contents of the third embodiment are the same as those of the first or second embodiment except for what is particularly described below.

In the stripes A and B generation step (S102), the stripe region generation unit 50 generates a plurality of stripe regions 32 (the first stripe region) by dividing in the y direction, for example, the writing region 30 of the target object 101 (substrate), and generates a plurality of stripe regions 37 (the second stripe region) whose some portion is overlapped with a corresponding stripe region 32 in the plurality of stripe regions 32 and whose longer direction has a relative angle θ (not being 0 degrees) to that of each corresponding stripe region 32 in the plurality of stripe regions 32. At this time, a plurality of stripe regions 37-1, 37-2, 37-3, and so on, corresponding to each stripe region 32, are generated.

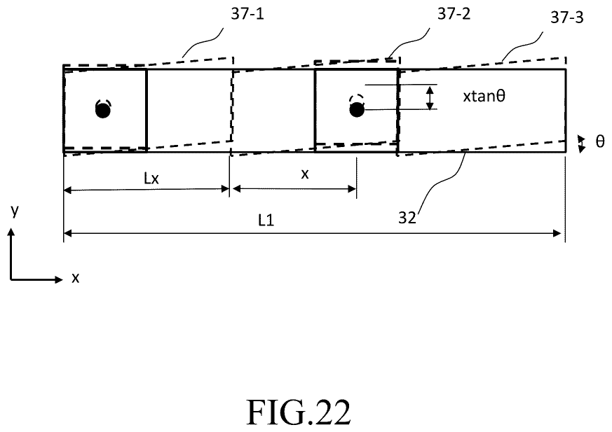

FIG. 22 is an illustration showing an example of a plurality of stripe regions whose respective angles in their longer directions are different from each other according to the third embodiment. FIG. 22 shows a plurality of stripe regions 37-1, 37-2, 37-3, and so on whose each longer direction has a relative angle θ to the longer direction of the stripe region 32. The widths W of the stripe regions 37-1, 37-2, 37-3, and so on are set to be the same as each other. Preferably, the stripe regions 37-1, 37-2, 37-3, and so on are arranged at a predetermined pitch. The stripe region 37-1 is rotated by the angle θ using the lower left corner of the stripe region 32 as a common corner being a fulcrum. The others such as the stripe regions 37-2, 37-3, and so on are arranged in order on the position shifted in the x direction from the lower left corner of the stripe region 32 by the pitch Lx. The relation is Lx<L1. Therefore, the lower left corner of each of the stripe regions 37-2, 37-3, and so on is located on the lower side of the two sides in the x direction of the stripe region 32.

Thus, by generating two or more stripe regions 37-1, 37-2, 37-3, and so on with respect to one stripe region 32, the maximum angle θmax (=W/Lx) can be larger than θmax shown in FIG. 11. FIG. 22 shows the case where, similar to the stripe region 37 shown in FIG. 12, the stripe regions 37-1, 37-2, and 37-3 are parallelograms. Thereby, it is possible to prevent that some portion of each of the stripe regions 37-1, 37-2, and 37-3 is overlapped with each other.

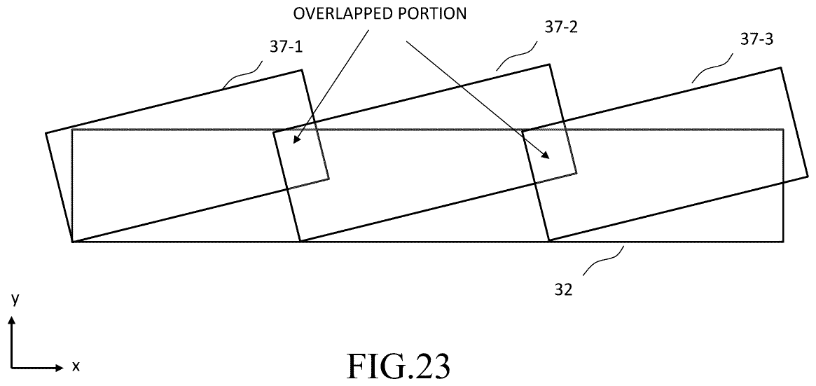

FIG. 23 is an illustration showing another example of a plurality of stripe regions whose respective angles in their longer directions are different from each other according to the third embodiment. FIG. 23 shows the case where each of the stripe regions 37-1, 37-2, 37-3, and so on is a rectangle. The other contents in FIG. 23 are the same as those of FIG. 22. In the example of FIG. 23, in order to form each of the stripe regions 37-1, 37-2, 37-3, and so on in a rectangle, some portions of them are mutually overlapped. Therefore, with respect to these overlapped portions, it is preferable to control to perform writing at the time of the previous stripe region (e.g., the stripe region 37-1), and no writing is performed at the later stripe region (e.g., the stripe region 37-2).

The contents of each step in or after the multiple writing step (S108) are the same as those of the first or second embodiment. The shift amount in the y direction at the Y-shifting step (S112) changes depending on a distance x in the x direction from the left end (writing starting side end) of the stripe region 37-1,-2, or -3. Specifically, as shown in FIG. 22, the shift amount of the Y-shifting is defined by xtanθ. Therefore, after moving from the stripe region 37-1 to the stripe region 37-2, the Y-shift amount is once reset. Similarly, after moving from the stripe region 37-2 to the stripe region 37-3, the Y-shift amount is once reset. Thereby, the maximum of the Y-shift amount can be reduced.

As described above, according to the third embodiment, the maximum relative angle θmax can be increased. Furthermore, compared to the first and second embodiments, the maximum value of the Y-shift amount can be reduced.

In each of the Embodiments described above, as stripe regions whose respective angles in their longer directions are different from each other, a group of two types of stripe regions 32 and 37 (37-1, 37-2, . . . ) having a relative angle θ is used, but it is not limited thereto. Three or more types of stripe regions may also preferably be formed as the stripe regions whose respective angles in their longer directions are different from each other.

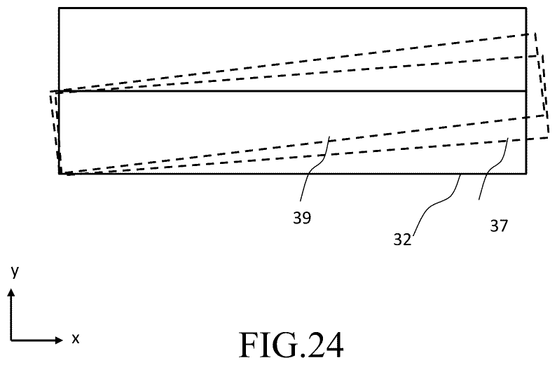

FIG. 24 is an illustration showing another example of a plurality of stripe regions whose respective angles in their longer directions are different from each other according to each of the embodiments. FIG. 24 shows the case where three types of the stripe regions 32, 37, and 39 whose angles in their longer directions are shifted from each other by a relative angle θ are formed. Further greater number of types of stripe regions whose angles are mutually shifted may also be formed. In any case, what is necessary is to perform writing to various types of stripe regions 32, 37, and 39 while carrying out the Y-shifting during the same tracking control (one tracking control).

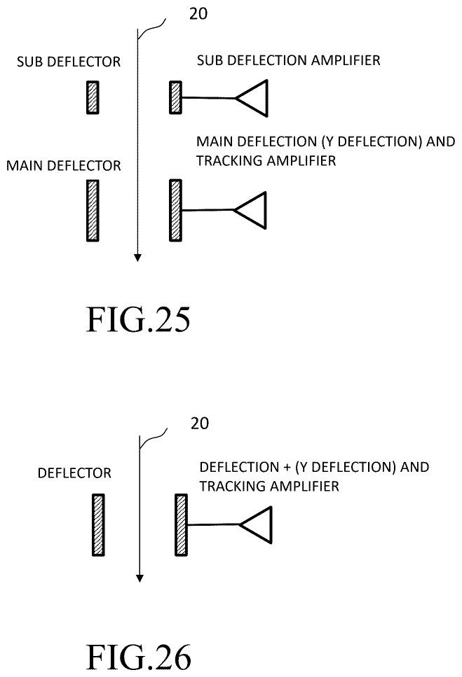

FIG. 25 is an illustration showing an example of the configuration of a deflector in each of the Embodiments. In FIG. 25, as explained in FIG. 1, a two-stage deflector (the main deflector 208 and the sub deflector 209) is arranged. In FIG. 25, for example, the main deflector 208 performs tracking control by beam deflection of all the multiple beams, and, further, deflects the multiple beams so that the irradiation region 34 of the multiple beams 20 may move between the stripe regions 32 and 37 in the same group. In other words, the main deflector 208 performs tracking control (beam deflection for tracking control) by beam deflection of all the multiple beams 20, and, further, deflects (beam deflection for Y-shifting) the multiple beams 20 so that the irradiation region 34 of the multiple beams 20 may move between the stripe regions 32 and 37 being corresponding to each other and having the relative angle θ between their longer directions. The sub deflector 209 performs beam deflection for shifting the shot position in the sub-irradiation region 29. However, it is not limited thereto.

FIG. 26 is an illustration showing another example of the configuration of the deflector in each of the Embodiments. FIG. 26 shows the case where a one-stage deflector (the main deflector 208 or the sub deflector 209) is arranged. In that case, the one-stage deflector performs all the beam deflections for tracking control, for Y-shifting, and for shifting the shot position in the sub-irradiation region 29.

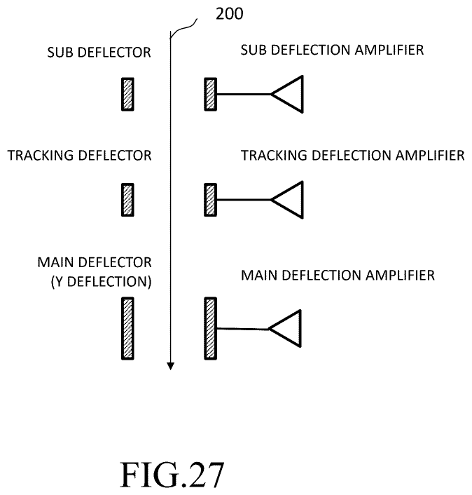

FIG. 27 is an illustration showing another example of the configuration of the deflector in each of the Embodiments. FIG. 27 shows the case where a three-stage deflector (the main deflector 208, the sub deflector 209, and a deflector further added) is arranged. In that case, for example, the first-stage deflector (the sub deflector 209) performs beam deflection for shifting the shot position in the sub-irradiation region 29. For example, the second-stage deflector (added deflector) (an example of the first deflector) executes tracking control (beam deflection for tracking control) by performing beam deflection of all the multiple beams. Then, for example, the third-stage deflector (the main deflector 208) (an example of the second deflector) deflects multiple beams so that the irradiation region of the multiple beams may move between the stripe regions 32 and 37 in the same group. Expressed in another way, the third-stage deflector (the main deflector 208) (an example of the second deflector) deflects (beam deflection for Y-shifting) the multiple beams 20 so that the irradiation region 34 of the multiple beams 20 may move between the stripe regions 32 and 37 being corresponding to each other and having a relative angle θ between their longer directions.

Thus, beam deflection for Y-shifting and beam deflection for tracking control may be performed by the same deflector or different deflectors.

Embodiments have been explained referring to specific examples described above. However, the present invention is not limited to these specific examples. For example, the stripe region 37 (37-1, 37-2, and so on) explained in the second or third embodiment may be preferably generated at the position shifted by a distance “s” in the y direction with respect to the corresponding stripe region 32 similarly to the case of FIG. 13.

Functions of processing described in each embodiment may be executed by a computer. A program for causing a computer to implement such functions of processing may be stored in a non-transitory tangible computer-readable storage medium such as a magnetic disk drive.

While the apparatus configuration, control method, and the like not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary. Furthermore, as a beam emitted from a light source, it is not limited to use a charged particle beam such as an electron beam, and therefore, a laser beam and the like can also be used.

Furthermore, any multi-beam writing apparatus, multi-beam writing method, and program that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multi-beam writing apparatus comprising:
a stage configured to be movable and to mount thereon a substrate which is to be written with multiple beams;
a stripe region generation circuit configured to generate a plurality of first stripe regions by dividing a writing region of the substrate such that a longer direction of each of the plurality of first stripe regions is in a first direction, and a plurality of second stripe regions by dividing the writing region of the substrate such that a longer direction of each of the plurality of second stripe regions is in a second direction having a predetermined relative angle to the first direction; and
a writing mechanism configured to repeat tracking control so that an irradiation region of the multiple beams follows a movement of the stage, and to perform writing, during each the tracking control, regarding, as a group, a first stripe region of the plurality of first stripe regions and a second stripe region of the plurality of second stripe regions where some regions of the first stripe region and the second stripe region are overlapped with each other, to the group of the first stripe region and the second stripe region while moving the irradiation region of the multiple beams between the first stripe region and the second stripe region in a same group during one movement of the stage to move the writing in a writing direction.

2. The apparatus according to claim 1, wherein each of the plurality of second stripe regions is generated by offsetting its reference position with respect to the first stripe region in the same group.

3. The apparatus according to claim 1, wherein the writing mechanism includes an optical mechanism which, in a case of performing writing to the plurality of second stripe regions, rotates, according to the predetermined relative angle, the irradiation region of the multiple beams at a time of performing writing to the plurality of first stripe regions.

4. The apparatus according to claim 1, wherein
the writing mechanism includes a deflector which performs the tracking control by beam deflection of all the multiple beams, and
the deflector, further, deflects the multiple beams so that the irradiation region of the multiple beams moves between the first stripe region and the second stripe region in the same group.

5. The apparatus according to claim 1, wherein the writing mechanism includes
a first deflector which performs the tracking control by beam deflection of all the multiple beams, and
a second deflector which deflects the multiple beams so that the irradiation region of the multiple beams moves between the first stripe region and the second stripe region in the same group.

6. A multi-beam writing method comprising:
placing a substrate to be written with multiple beams on a stage being movable;
generating a plurality of first stripe regions by dividing a writing region of the substrate such that a longer direction of each of the plurality of first stripe regions is in a first direction, and a plurality of second stripe regions by dividing the writing region of the substrate such that a longer direction of each of the plurality of second stripe regions is in a second direction having a predetermined relative angle to the first direction; and
repeating tracking control so that an irradiation region of the multiple beams follows a movement of the stage, and performing writing, during each the tracking control, regarding, as a group, a first stripe region of the plurality of first stripe regions and a second stripe region of the plurality of second stripe regions where some regions of the first stripe region and the second stripe region are overlapped with each other, to the group of the first stripe region and the second stripe region while moving the irradiation region of the multiple beams between the first stripe region and the second stripe region in a same group during one movement of the stage to move the writing in a writing direction.
